(19) United States
(12) Patent Application Publication
(10) Pub. No.: US 2016/0179234 A1
(43) Pub. Date: Jun. 23, 2016

(54) TOUCH SENSOR FOR TOUCH SCREEN PANEL, MANUFACTURING METHOD THEREOF, AND TOUCH SCREEN PANEL INCLUDING SAME

(71) Applicant: AMOSENSE CO., LTD., Cheonan-si, Chungcheongnam-do (KR)

(72) Inventors: Sungbaek DAN, Gyeonggi-do (KR); Jinsu HWANG, Gyeonggi-do (KR)

(21) Appl. No.: 14/902,274

(22) PCT Filed: Jul. 3, 2014
(86) PCT No.: PCT/KR2014/005963

§ 371 Date: Dec. 30, 2015

(30) Foreign Application Priority Data
Jul. 3, 2013 (KR) 10-2013-0077950
Aug. 19, 2013 (KR) 10-2013-0097975

(51) Int. Cl. G06F 3/041; G03F 7/32; G03F 7/36; G03F 7/20

(52) U.S. Cl. CPC G06F 3/041; G03F 7/20; G03F 7/32; G03F 7/36; G06F 2203/04103

(57) ABSTRACT

Disclosed are a touch sensor for a touch screen panel, a method of manufacturing the same, and a touch screen panel including the same. The touch sensor is manufactured by forming a thin-film deposition layer through deposition on a transparent substrate, etching the portion of the thin-film deposition layer other than the portion corresponding to a touch-sensing circuit pattern and plating the thin-film deposition layer that remains on the transparent substrate, thus increasing the strength of adhesion between the transparent substrate and the touch-sensing circuit pattern, precisely forming the touch-sensing circuit pattern having a fine line width, and increasing the durability of the touch-sensing circuit pattern to thus ensure operational reliability.

### TECHNICAL FIELD

The present invention relates to a touch sensor for a touch screen panel and, more particularly, to a touch sensor having increased strength of adhesion to a transparent substrate, a method of manufacturing the same, and a touch screen panel including the same.

This application claims the benefit of Korean Patent Application Nos. KR 10-2013-0077950, filed Jul. 3, 2013, and KR 10-2013-0097975, filed Aug. 19, 2013, which are hereby incorporated by reference in their entirety into this application.

### BACKGROUND ART

Generally, a touch screen panel is manufactured in a manner in which a touch sensor comprising a transparent film and a transparent electrode is laminated with cover glass.

The touch sensor is manufactured by coating one surface of the transparent film with an electrode material, for example ITO (Indium Tin Oxide), and then performing etching to form a sensing electrode.

With reference to FIG. 1, the touch screen panel 1 is configured such that two touch sensors 1c and reinforced glass 1d for covering the touch sensors 1c are sequentially layered using transparent adhesive layers 1b on a display panel 1a.

Specifically, a typical touch screen panel is mainly provided in the form of a GFF type, which includes two touch sensors configured such that an ITO sensing electrode is formed on a film substrate, and reinforced glass 1d. Each of the two sensors includes an X-axis sensor or a Y-axis sensor.

However, the conventional touch sensor for a touch screen panel including a film substrate and an ITO sensing electrode is problematic because of the slow touch speed and difficulty in realizing multi-touch capability due to the high resistance of the ITO electrode on a screen having a size of 13 inches or more.

Also, indium, which is the main component of ITO (Indium Tin Oxide), is a rare element that is being depleted, and is expensive due to the limited reserves thereof, undesirably increasing the cost of manufacturing the touch screen panel.

Also, the ITO (Indium Tin Oxide) electrode, which has a high processing temperature, is difficult to apply to flexible substrates, and may undergo frequent cracking due to the poor mechanical properties thereof, making it unsuitable for application to flexible displays.

Also, the ITO electrode is problematic in that wastewater is discharged through an etching process upon dry deposition, undesirably causing environmental pollution. Furthermore, when it is used for OLEDs, indium may diffuse into the organic layer.

In particular, the ITO electrode, which has high resistance, may excessively increase the consumption of power in large-area touch screen panels having a size of 13 inches or more.

Also, a touch sensor may be fabricated by forming AgNW (Silver nano Wire) on the entire surface of the transparent film and forming a transparent electrode through etching. The formation of the transparent electrode using AgNW (Silver nano Wire) results in a fast touch speed thanks to low resistance, but also results in low transparency.

Also, since a conventional touch sensor is mostly fabricated through exposure, development, and etching, damage such as scratching may be caused on the transparent film, undesirably incurring optical degradation.

Also, a conventional touch screen panel includes two touch sensors 1c, in which each of the X-axis and Y-axis sensors is formed on the transparent film, undesirably complicating the manufacturing process and increasing manufacturing costs. Moreover, limitations are imposed on the realization of slim products.

### DISCLOSURE

### Technical Problem

Accordingly, the present invention has been made keeping in mind the above problems encountered in the related art, and an object of the present invention is to provide a touch sensor for a touch screen panel, a method of manufacturing the same, and a touch screen panel including the same, wherein the touch sensor is configured such that the strength of adhesion between a transparent substrate and a touch-sensing circuit pattern may be increased, thus precisely forming a touch-sensing circuit pattern having a fine line width and increasing the durability of the touch-sensing circuit pattern, thereby assuring the operational reliability of products owing to the consistent touch speed and multi-touch capability.

### Technical Solution

In order to accomplish the above object, an aspect of the present invention provides a touch sensor for a touch screen panel, comprising: a transparent substrate; and a touch-sensing circuit pattern formed on the transparent substrate so as to sense a touch on the touch screen panel, wherein the touch-sensing circuit pattern comprises a thin-film deposition layer formed through deposition and a plating layer formed through plating on the thin-film deposition layer.

In the present invention, the thin-film deposition layer may comprise any one selected from among chromium (Cr), molybdenum (Mo), titanium (Ti), tungsten (W), nickel-chromium (NiCr), titanium-tungsten (TiW), and copper (Cu).

In the present invention, the thin-film deposition layer may comprise thermally evaporated copper.

In the present invention, the thin-film deposition layer may comprise an oxide film or a nitride film.

In the present invention, the oxide film may comprise any one selected from among titanium oxide (TiO₂), chromium oxide (CrO₂), copper oxide (CuO), nickel oxide (NiO), aluminum oxide (Al₂O₃), and silver oxide (AgO), and the nitride film may comprise titanium nitride (TiN) or copper nitride (CuN).

The touch sensor may further comprise a plating facilitation layer disposed between the thin-film deposition layer and the plating layer.

In the present invention, the plating facilitation layer may comprise any one selected from among copper (Cu), nickel (Ni), silver (Ag), gold (Au), tin (Sn), aluminum (Al), and palladium (Pd).

In the present invention, the touch-sensing circuit pattern may comprise an X-axis sensing circuit part having a plurality of X-axis electrodes spaced apart from each other in a transverse direction and a Y-axis sensing circuit part having a plurality of Y-axis electrodes spaced apart from each other in a longitudinal direction, and the X-axis sensing circuit part and the Y-axis sensing circuit part may be formed on the same surface of the transparent substrate.

In the present invention, the touch-sensing circuit pattern may comprise an X-axis sensing circuit part having a plurality of X-axis electrodes spaced apart from each other in a transverse direction, which is provided on one of two surfaces of the transparent substrate, and a Y-axis sensing circuit part having a plurality of Y-axis electrodes spaced apart from each other in a longitudinal direction, which is provided on a remaining surface thereof.

Another aspect of the present invention provides a method of manufacturing a touch sensor for a touch screen panel, comprising: forming a thin-film deposition layer through deposition on a transparent substrate; etching a portion of the thin-film deposition layer other than a portion corresponding to a touch-sensing circuit pattern; and plating the thin-film deposition layer that remains on the transparent substrate after the etching.

In the present invention, the method may further comprise forming a photosensitive conductive layer on the thin-film deposition layer after the forming the thin-film deposition layer and before the etching, wherein the etching comprises: forming a photosensitive layer on the photosensitive conductive layer; exposing the photosensitive layer and developing the photosensitive layer using a developer solution, thus simultaneously removing portions of the photosensitive layer and the photosensitive conductive layer other than a pattern corresponding to a touch-sensing circuit pattern; etching the thin-film deposition layer in a shape corresponding to the touch-sensing circuit pattern; and removing the remaining photosensitive layer that covers the thin-film deposition layer.

In the present invention, the forming the photosensitive conductive layer may comprise forming the photosensitive layer through any one selected from among comma roll coating, gravure coating, doctor blading, and spraying.

In the present invention, the forming the photosensitive conductive layer may comprise forming the photosensitive layer through electrospinning.

In the present invention, the photosensitive conductive layer may comprise an aluminum layer or an aluminum alloy layer containing aluminum.

In the present invention, the developer solution may be a carbonate-based high-alkaline solution having a pH of 10 or more.

In the present invention, the developer solution may include K₂CO₃ or Na₂CO₃.

### Advantageous Effects

According to the present invention, the touch sensor for a touch screen panel is configured such that the strength of adhesion between a transparent substrate and a touch-sensing circuit pattern is increased, thus precisely forming a touch-sensing circuit pattern having a fine line width and increasing the durability of the touch-sensing circuit pattern.

According to the present invention, the touch sensor for a touch screen panel enables a consistent touch speed and multi-touch capability, thus ensuring the operational reliability of products. Furthermore, the touch-sensing circuit pattern is not damaged even in the event of warpage, making it suitable for application to flexible displays, and the operational reliability of products can be assured due to the consistent touch speed and multi-touch capability of the flexible display.

According to the present invention, the touch-sensing circuit pattern is formed through deposition and plating, thereby simplifying the manufacturing process and significantly reducing manufacturing costs.

### DESCRIPTION OF DRAWINGS

FIG. 1 illustrates a conventional touch screen panel;

FIG. 2 is a cross-sectional view illustrating a touch sensor for a touch screen panel according to an embodiment of the present invention;

FIG. 3 is a cross-sectional view illustrating a touch sensor for a touch screen panel according to another embodiment of the present invention;

FIG. 4 is a perspective view illustrating a touch sensor for a touch screen panel according to an embodiment of the present invention;

FIGS. 5 and 6 are cross-sectional views illustrating touch sensors for touch screen panels according to embodiments of the present invention;

FIGS. 7 to 11 are schematic views illustrating touch screen panels according to embodiments of the present invention;

FIG. 12 is a flowchart illustrating the process of manufacturing a touch sensor for a touch screen panel according to an embodiment of the present invention;

FIG. 13 schematically illustrates the process of manufacturing the touch sensor of FIG. 12;

FIG. 14 is a flowchart illustrating the process of manufacturing a touch sensor for a touch screen panel according to another embodiment of the present invention;

FIG. 15 schematically illustrates the process of manufacturing the touch sensor of FIG. 14;

FIG. 16 is a flowchart illustrating the process of manufacturing a touch sensor for a touch screen panel according to still another embodiment of the present invention;

FIG. 17 schematically illustrates the process of manufacturing the touch sensor of FIG. 16; and

FIG. 18 schematically illustrates the process of manufacturing a touch sensor for a touch screen panel according to yet another embodiment of the present invention.

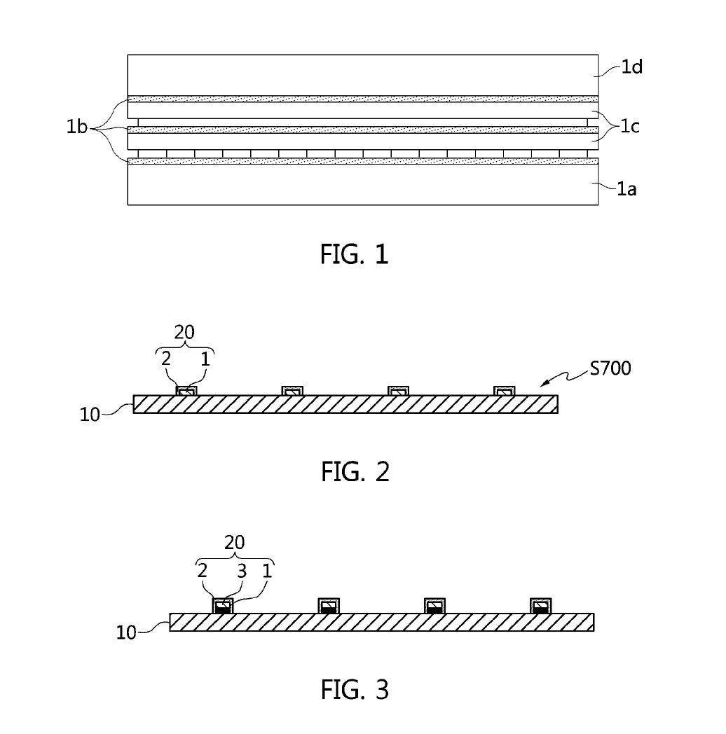

### DESCRIPTION OF THE REFERENCE NUMERALS IN THE DRAWINGS

1: thin-film deposition layer

2: plating layer

3: plating facilitation layer

4: photosensitive layer

4a: cover pattern

5: mask

5a: pattern hole

6: photosensitive conductive layer

10: transparent substrate

11: touch screen panel cover substrate

12: first transparent substrate

13: second transparent substrate

20: touch-sensing circuit pattern

21: X-axis sensing circuit part

22: Y-axis sensing circuit part

30: display panel unit

40: transparent adhesive layer

### BEST MODE

The present invention will be described in detail below with reference to the accompanying drawings. In the following description, redundant descriptions and detailed descriptions of known functions and elements that may unnecessarily make the gist of the present invention obscure will be omitted. Embodiments of the present invention are provided to fully describe the present invention to those having ordinary knowledge in the art to which the present invention pertains. Accordingly, in the drawings, the shapes and sizes of elements may be exaggerated for the sake of clearer description.

FIG. 2 is a cross-sectional view illustrating the touch sensor according to an embodiment of the present invention. With reference to FIG. 2, the touch sensor for a touch screen panel according to an embodiment of the present invention includes a transparent substrate 10 and a touch-sensing circuit pattern 20 formed on the transparent substrate 10 so as to sense a touch on the touch screen panel.

The touch-sensing circuit pattern 20 includes a thin-film deposition layer 1 formed through deposition and a plating layer 2 formed through plating on the thin-film deposition layer 1.

The touch-sensing circuit pattern 20 is formed so as to have a line width that is so fine that it cannot be recognized with the naked eye, for example, 15 μm or less, and preferably 3 μm or less.

The transparent substrate 10 may be a transparent PI film, and may include any one of a PEN (Polyethylene Naphthalate) film, a PET (Polyethylene Terephthalate) film, a PC (Polycarbonate) film, and a PSS (Polystyrene sulfonate) film, or may include a film made of a transparent material such as engineering plastics.

Also, the transparent substrate 10 may be reinforced glass, or a reinforced coating film configured such that a reinforced coating layer for increasing hardness is formed on the surface of a film substrate. The film substrate may be a transparent PI film, and may include any one of a PEN (Polyethylene Naphthalate) film, a PET (Polyethylene Terephthalate) film, a PC (Polycarbonate) film, and a PSS (Polystyrene sulfonate) film. Also, any synthetic resin film may be used so long as it may be subjected to a reinforced coating process.

The reinforced coating layer may be formed using a resin including silicon (Si) or ceramic, or through vacuum deposition. Alternatively, any coating layer may be used, so long as it increases the hardness of one surface of the film substrate 11 in order to improve resistance to scratching and cracking.

The reinforced coating layer preferably has a thickness of 0.3 mm or less so as to be flexible, and thus to be suitable for use in a flexible touch screen panel.

The transparent substrate 10 may be a touch screen panel cover substrate for covering and protecting the screen of a display panel unit in the touch screen panel, and the touch screen panel cover substrate may be the reinforced glass or reinforced coating film as mentioned above.

The transparent substrate 10 functions as the touch screen panel cover substrate, and the touch-sensing circuit pattern 20 is integrally formed on one surface of the touch screen panel cover substrate, thus realizing a slim and lightweight touch screen panel.

As such, one surface of the touch screen panel cover substrate is the internal surface of the touch screen panel, that is, the surface facing the display panel unit, meaning the surface other than the outward surface, which is the surface exposed to the outside when mounted to the display panel unit.

The thin-film deposition layer 1 is formed through vacuum deposition, and may be made of chromium (Cr). In addition to Cr, alternatively useful is any one selected from among molybdenum (Mo), titanium (Ti), tungsten (W), nickel-chromium (NiCr), titanium-tungsten (TiW), and copper (Cu), or an alloy comprising at least two selected from among molybdenum (Mo), titanium (Ti), tungsten (W), nickel-chromium (NiCr), titanium-tungsten (TiW), and copper, or an alloy comprising at least one selected from among molybdenum (Mo), titanium (Ti), tungsten (W), nickel-chromium (NiCr), titanium-tungsten (TiW), and copper. The metal thin-film layer 2 is made of a metal that strongly adheres to the substrate 1 for a touch screen panel and minimizes the scattering of light.

The thin-film deposition layer 1 is attached onto the transparent substrate 10 through vacuum deposition, thus exhibiting high adhesion to the transparent substrate 10 and maintaining the thin-film deposition layer 1 firmly attached to the transparent substrate 10 without being separated from the transparent substrate 10, even in the event of warpage of the transparent substrate 10.

The thin-film deposition layer 1 is preferably made of a metal having a dark color so as to absorb light, and more preferably a metal having a blackish color after deposition, that is, having a light reflectance of 30% or less.

The thin-film deposition layer 1 having a light reflectance of 30% or less may minimize the scattering of light to increase transparency and to prevent glare, thus improving the visibility of the touch screen panel.

The thin-film deposition layer 1 preferably has a thickness of 500 to 10,000 Å, and the thickness thereof is set to 1000 Å in the present invention.

The thin-film deposition layer 1 is preferably composed of thermally evaporated Cu, and this Cu has an affinity for plating and thus has high strength of adhesion to the plating layer 2 and shows a black color upon thermal evaporation.

The thin-film deposition layer 1 may be an oxide film or a nitride film, and the oxide film may be any one selected from among titanium oxide (TiO₂), chromium oxide (CrO₂), copper oxide (CuO), nickel oxide (NiO), aluminum oxide (Al₂O₃), and silver oxide (AgO), and the nitride film may be titanium nitride (TiN) or copper nitride (CuN).

The plating layer 2 may include any one selected from among gold (Au), silver (Ag), and copper (Cu), and may be an alloy including at least one selected from among gold (Au), silver (Ag), and copper (Cu).

The plating layer 2 functions to decrease resistance of the touch-sensing circuit pattern 20, and the thickness thereof may be controlled so that the total resistance of the touch-sensing circuit pattern 20 is set to be low.

The plating layer 2 is formed to enclose the outer circumference of the thin-film deposition layer 1, and may cover, for example, the surface and both sides of the thin-film deposition layer 1.

With reference to FIG. 3, the touch-sensing circuit pattern 20 may further include a plating facilitation layer 3 disposed between the thin-film deposition layer 1 and the plating layer 2.

The plating facilitation layer 3 facilitates the plating on the thin-film deposition layer 1 and also increases the strength of adhesion between the plating layer 2 and the thin-film deposition layer 1, thus further improving durability of the touch-sensing circuit pattern 20 and maintaining the shape of the touch-sensing circuit pattern 20 even in the event of deformation of the transparent substrate 10, such as warpage.

The plating facilitation layer 3 may be composed of any one selected from among copper (Cu), nickel (Ni), silver (Ag), gold (Au), tin (Sn), aluminum (Al), and palladium (Pd), but any metal may be used so long as it has an affinity for plating.

The plating facilitation layer 3 is formed on the thin-film deposition layer 1, and the plating layer 2 is provided so as to enclose the plating facilitation layer 3 and the thin-film deposition layer 1, and more specifically, is provided so as to cover the surface and both sides of the plating facilitation layer 3 and both sides of the thin-film deposition layer 1.

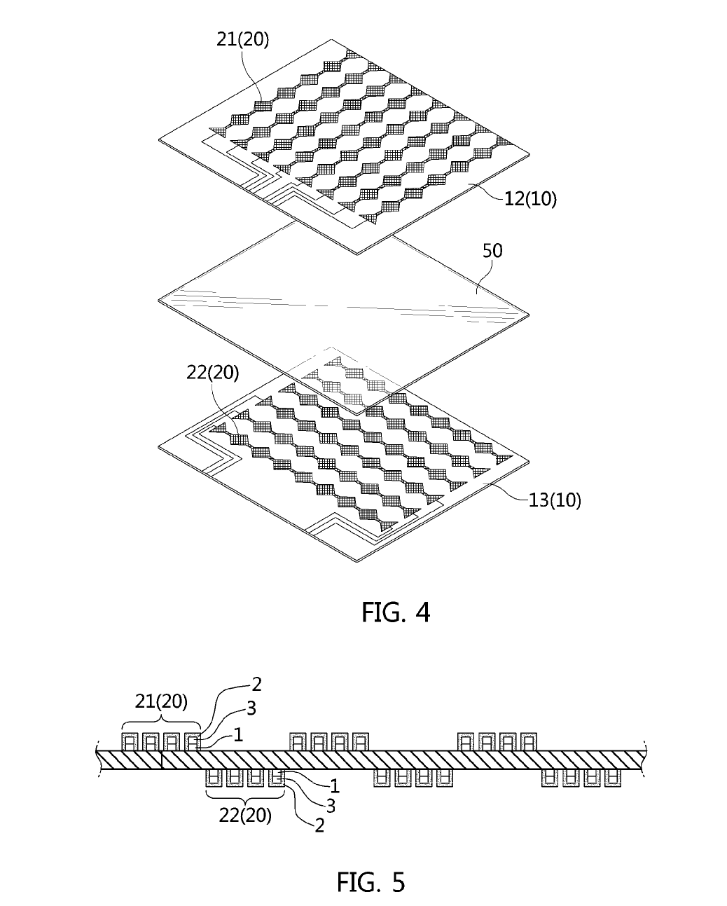

With reference to FIG. 4, the touch-sensing circuit pattern 20 is provided in the form of a circuit that is able to sense a touch, and comprises an X-axis sensing circuit part 21 having a plurality of X-axis electrodes spaced apart from each other in a transverse direction or a Y-axis sensing circuit part 22 having a plurality of Y-axis electrodes spaced apart from each other in a longitudinal direction.

The transparent substrate 10 includes a first transparent substrate 12 and a second transparent substrate 13, and the touch-sensing circuit pattern 20 includes an X-axis sensing circuit part 21 having a plurality of X-axis electrodes spaced apart from each other in a transverse direction, which is provided on the first transparent substrate 12, and a Y-axis sensing circuit part 22 having a plurality of Y-axis electrodes spaced apart from each other in a longitudinal direction, which is provided on the second transparent substrate 13.

The plurality of X-axis electrodes spaced apart from each other in the transverse direction and the plurality of Y-axis electrodes spaced apart from each other in the longitudinal direction are connected to an external circuit via silver trace electrodes, and the external circuit is exemplified by an electrostatic multi-touch controller, and the electrostatic multi-touch controller is electrically connected to the main processor of the corresponding electronic device.

The X-axis and Y-axis electrodes are configured such that touch sensor electrodes in a diamond-shaped metal mesh form are electrically connected.

With reference to FIG. 5, the touch-sensing circuit pattern 20 includes an X-axis sensing circuit part 21 having a plurality of X-axis electrodes spaced apart from each other in a transverse direction, provided on one of the two surfaces of the transparent substrate 10, and a Y-axis sensing circuit part 22 having a plurality of Y-axis electrodes spaced apart from each other in a longitudinal direction, provided on the other surface thereof.

The two surfaces of the transparent substrate 10 are respectively provided with the X-axis sensing circuit part 21 and the Y-axis sensing circuit part 22, thus reducing material costs and realizing a slim and lightweight touch screen panel.

The X-axis sensing circuit part 21 or the Y-axis sensing circuit part 22 comprises a thin-film deposition layer 1 formed through deposition and a plating layer 2 formed through plating on the thin-film deposition layer 1, and may further comprise a plating facilitation layer 3 disposed between the thin-film deposition layer 1 and the plating layer 2.

The thin-film deposition layer 1, the plating layer 2, and the plating facilitation layer 3 are described above, and thus a redundant description thereof is omitted.

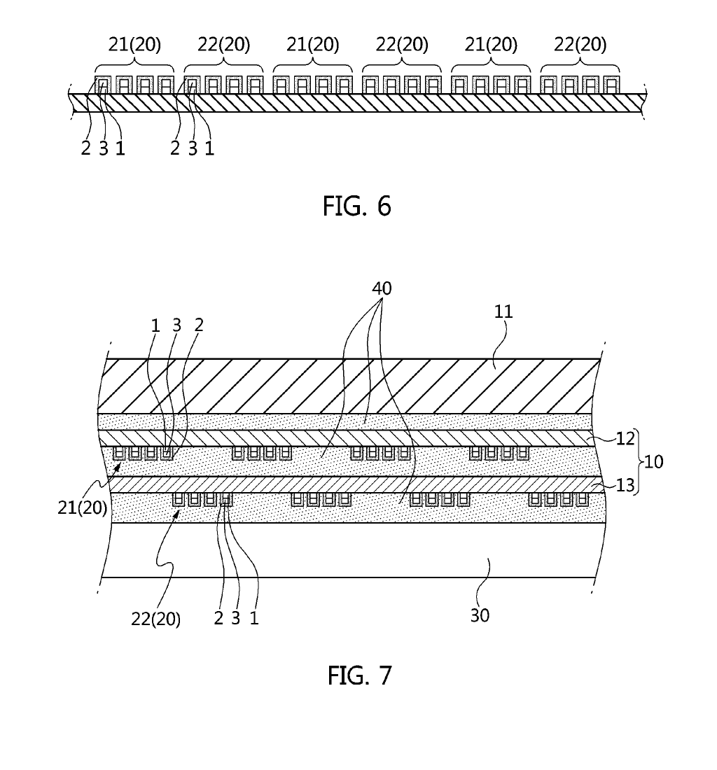

With reference to FIG. 6, as the touch-sensing circuit pattern 20, an X-axis sensing circuit part 21 having a plurality of X-axis electrodes spaced apart from each other in a transverse direction, and a Y-axis sensing circuit part 22 having a plurality of Y-axis electrodes spaced apart from each other in a longitudinal direction, may be formed on the same surface of the transparent substrate 10.

On either of the two surfaces of the transparent substrate 10, the X-axis sensing circuit part 21 and the Y-axis sensing circuit part 22 are formed together, thus reducing material costs, improving optical properties, and realizing a slim and lightweight touch screen panel.

The X-axis sensing circuit part 21 or the Y-axis sensing circuit part 22 comprises a thin-film deposition layer 1 formed through deposition and a plating layer 2 formed through plating on the thin-film deposition layer 1, and may further comprise a plating facilitation layer 3 disposed between the thin-film deposition layer 1 and the plating layer 2.

The thin-film deposition layer 1, the plating layer 2, and the plating facilitation layer 3 are described above, and thus a redundant description thereof is omitted.

With reference to FIGS. 7 to 11, the touch screen panel according to an embodiment of the present invention comprises a display panel unit 30 for outputting a screen, a touch screen panel cover substrate 11 for covering and protecting the screen of the display panel unit 30, and a touch-sensing circuit pattern 20 interposed between the display panel unit 30 and the touch screen panel cover substrate 11 so as to sense a touch on the touch screen panel.

The touch screen panel cover substrate 11 may be, for example, reinforced glass, or a reinforced coating film configured such that a reinforced coating layer for increasing hardness is formed on the surface of a film substrate, as in the transparent substrate 10, and the touch-sensing circuit pattern 20 includes a thin-film deposition layer 1, a plating facilitation layer 3, and a plating layer 2, which are as described above, and thus a redundant description thereof is omitted.

More specifically, referring to FIG. 7, the touch screen panel according to an embodiment of the present invention further comprises a first transparent substrate 12 and a second transparent substrate 13, which are spaced apart from each other between the display panel unit 30 and the touch screen panel cover substrate 11, and the touch-sensing circuit pattern 20 comprises an X-axis sensing circuit part 21 having a plurality of X-axis electrodes spaced apart from each other in a transverse direction, provided on the first transparent substrate 12, and a Y-axis sensing circuit part 22 having a plurality of Y-axis electrodes spaced apart from each other in a longitudinal direction, provided on the second transparent substrate 13.

The display panel unit 30 and the touch screen panel cover substrate 11, and the first transparent substrate 12 and the second transparent substrate 13, which are spaced apart from each other between the display panel unit 30 and the touch screen panel cover substrate 11, are attached to each other using transparent adhesive layers 40, and the transparent adhesive layers 40 may be exemplified by an OCA (Optically Clear Adhesive) film.

Respective transparent adhesive layers 40 are provided between the touch screen panel cover substrate 11 and the first transparent substrate 12, between the first transparent substrate 12 and the second transparent substrate 13, and between the display panel unit 30 and the second transparent substrate 13.

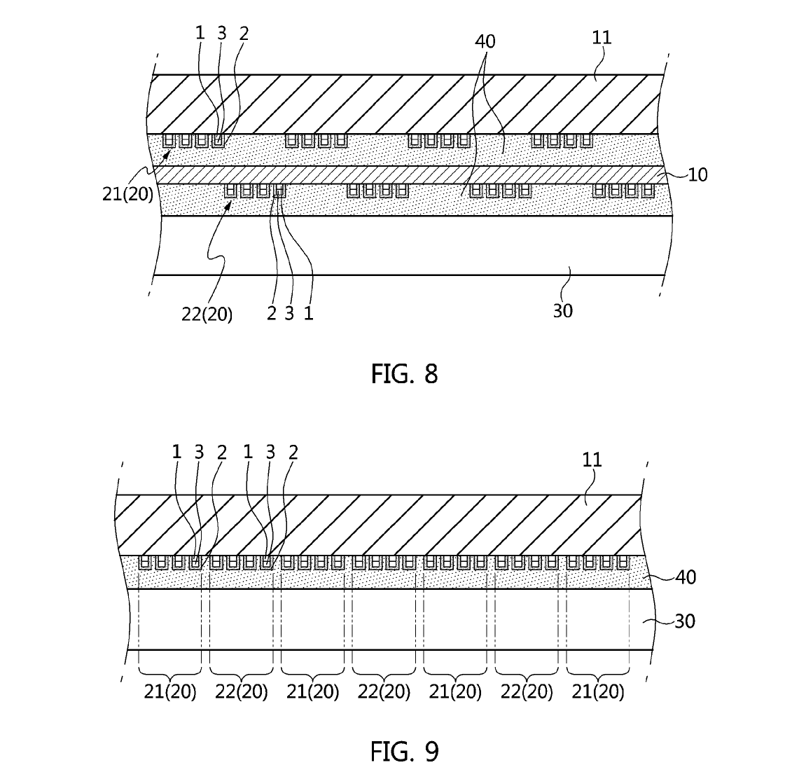

With reference to FIG. 8, the touch screen panel according to an embodiment of the present invention further comprises a transparent substrate 10 spaced apart from the touch screen panel cover substrate 11, and the touch-sensing circuit pattern 20 includes an X-axis sensing circuit part 21 having a plurality of X-axis electrodes spaced apart from each other in a transverse direction, provided on one of the touch screen panel cover substrate 11 and the transparent substrate 10, and a Y-axis sensing circuit part 22 having a plurality of Y-axis electrodes spaced apart from each other in a longitudinal direction, provided on the other one thereof.

Of the X-axis sensing circuit part 21 and the Y-axis sensing circuit part 22, one is formed on one surface of the touch screen panel, and the other is formed on one surface of the transparent substrate 10.

The display panel unit 30 and the touch screen panel cover substrate 11, and the transparent substrate 10, which is spaced apart from the display panel unit 30 and the touch screen panel cover substrate 11, are attached to each other using transparent adhesive layers 40, the transparent adhesive layers 40 being exemplified by an OCA film.

Respective transparent adhesive layers 40 are provided between the display panel unit 30 and the transparent substrate 10 and between the transparent substrate 10 and the touch screen panel cover substrate 11.

Either of the X-axis sensing circuit part 21 and the Y-axis sensing circuit part 22 is integrally formed on one surface of the touch screen panel cover substrate 11, thus reducing material costs and realizing high transparency and a slim and lightweight touch screen panel.

With reference to FIG. 9, the touch-sensing circuit pattern 20 may comprise an X-axis sensing circuit part 21, having a plurality of X-axis electrodes spaced apart from each other in a transverse direction, and a Y-axis sensing circuit part 22, having a plurality of Y-axis electrodes spaced apart from each other in a longitudinal direction, which are provided on one surface of the touch screen panel cover substrate 11.

The touch-sensing circuit pattern 20 is configured such that the X-axis sensing circuit part 21 and the Y-axis sensing circuit part 22 are formed together on one surface of the touch screen panel cover substrate 11, thus reducing material costs, improving optical properties, and realizing a slim and lightweight touch screen panel.

The display panel unit 30 and the touch screen panel cover substrate 11 are attached to each other using a transparent adhesive layer 40, and the transparent adhesive layer 40 may be exemplified by an OCA film.

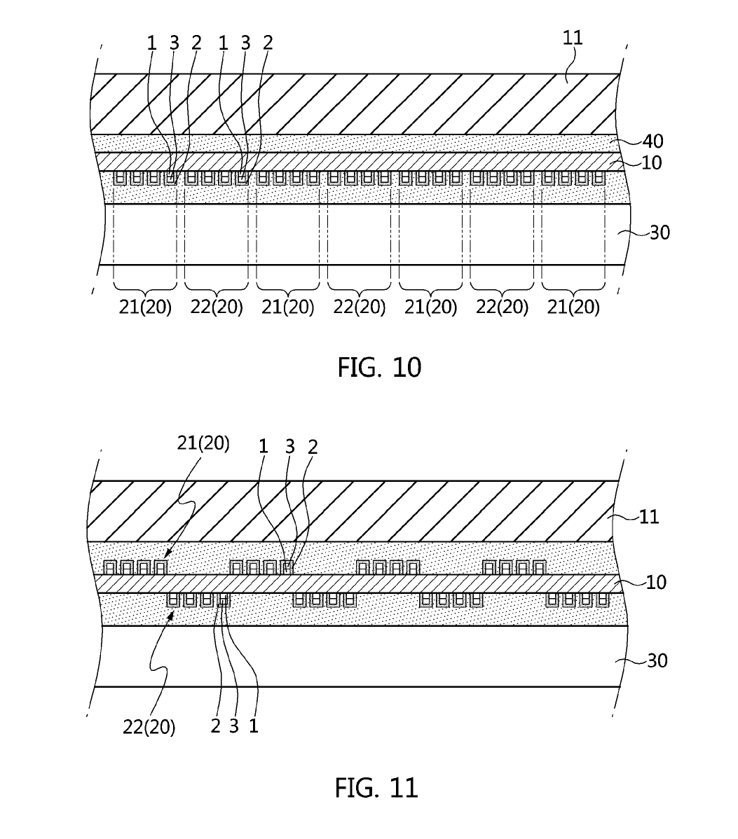

With reference to FIG. 10, the touch screen panel according to an embodiment of the present invention further comprises a transparent substrate 10 spaced apart from the touch screen panel cover substrate 11, and the touch-sensing circuit pattern 20 may comprise an X-axis sensing circuit part 21 having a plurality of X-axis electrodes spaced apart from each other in a transverse direction and a Y-axis sensing circuit part 22 having a plurality of Y-axis electrodes spaced apart from each other in a longitudinal direction, and the X-axis sensing circuit part 21 and the Y-axis sensing circuit part 22 may be formed on the same surface of the transparent substrate 10.

The touch-sensing circuit pattern 20 is configured such that the X-axis sensing circuit part 21 and the Y-axis sensing circuit part 22 may be formed on the same surface of the transparent substrate 10, thus reducing material costs, improving optical properties, and realizing a slim and lightweight touch screen panel.

Respective transparent adhesive layers 40 are provided between the display panel unit 30 and the transparent substrate 10 and between the transparent substrate 10 and the touch screen panel cover substrate 11.

Either of the X-axis sensing circuit part 21 and the Y-axis sensing circuit part 22 is integrally formed on one surface of the touch screen panel cover substrate 11, thus reducing material costs and realizing high transparency and a slim and lightweight touch screen panel.

With reference to FIG. 11, the touch screen panel according to an embodiment of the present invention further comprises a transparent substrate 10 spaced apart from the touch screen panel cover substrate 11, and the touch-sensing circuit pattern 20 may comprise an X-axis sensing circuit part 21 having a plurality of X-axis electrodes spaced apart from each other in a transverse direction, provided on one surface of the transparent substrate 10, and a Y-axis sensing circuit part 22 having a plurality of Y-axis electrodes spaced apart from each other in a longitudinal direction, provided on the other surface of the transparent substrate 10.

Respective transparent adhesive layers 40 are provided between the display panel unit 30 and the transparent substrate 10 and between the transparent substrate 10 and the touch screen panel cover substrate 11.

Either of the X-axis sensing circuit part 21 and the Y-axis sensing circuit part 22 is integrally formed on one surface of the touch screen panel cover substrate 11, thus reducing material costs and realizing high transparency and a slim and lightweight touch screen panel.

The X-axis sensing circuit part 21 and the Y-axis sensing circuit part 22 are provided on respective surfaces of the transparent substrate 10, thus reducing material costs and realizing a slim and lightweight touch screen panel.

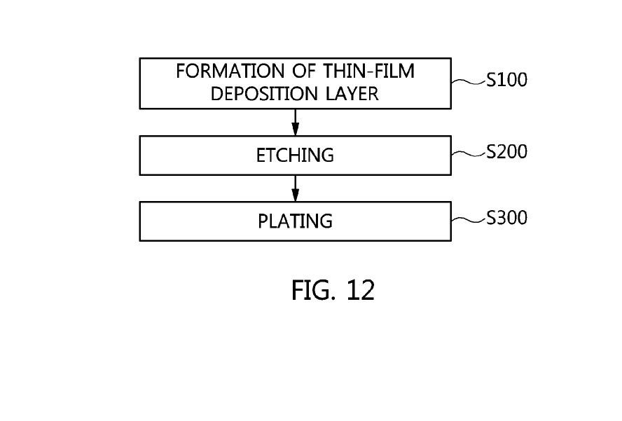

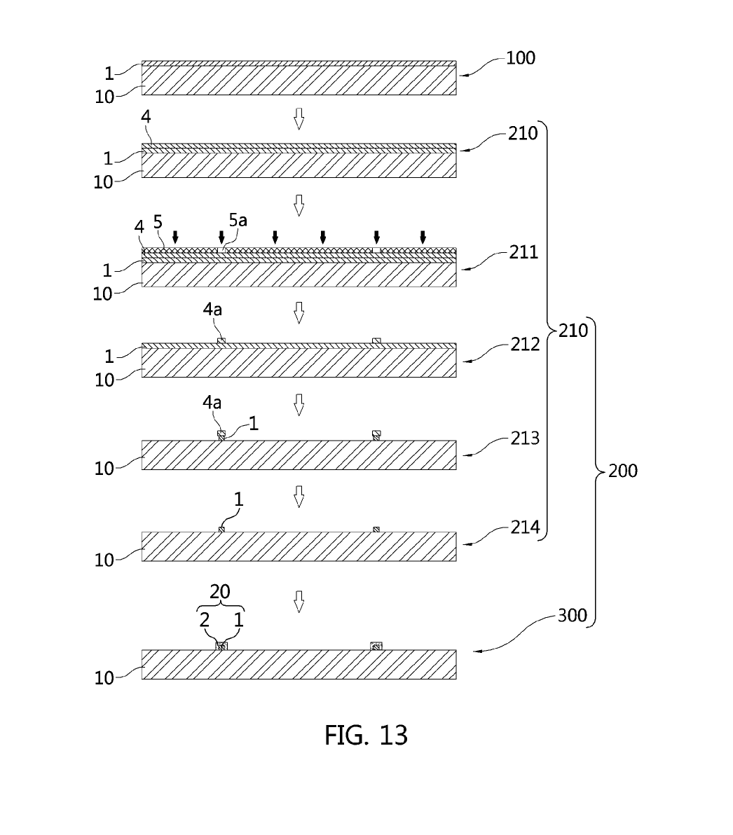

With reference to FIGS. 12 and 13, the method of manufacturing a touch sensor for a touch screen panel according to an embodiment of the present invention comprises forming a thin-film deposition layer 1 through deposition on a transparent substrate 10 (S100), etching a portion of the thin-film deposition layer 1 other than the portion corresponding to a touch-sensing circuit pattern (S200), and plating the thin-film deposition layer 1 that remains on the transparent substrate 10 after S200 (S300).

The step of forming the thin-film deposition layer 1 (S100) is performed through vacuum deposition to form a thin-film deposition layer 1, and the vacuum deposition process may include any one selected from among thermal evaporation, e-beam evaporation, laser deposition, sputtering, and arc ion plating.

The vacuum deposition is preferably carried out using, as a target material, any one selected from among chromium (Cr), molybdenum (Mo), titanium (Ti), tungsten (W), nickel-chromium (NiCr), titanium-tungsten (TiW), and copper (Cu), or an alloy comprising at least two selected from among molybdenum (Mo), titanium (Ti), tungsten (W), nickel-chromium (NiCr), titanium-tungsten (TiW), and copper (Cu), or an alloy comprising at least one selected from among molybdenum (Mo), titanium (Ti), tungsten (W), nickel-chromium (NiCr), titanium-tungsten (TiW), and copper (Cu).

The step of forming the thin-film deposition layer 1 (S100) is preferably performed by subjecting copper (Cu) to thermal evaporation. The thin-film deposition layer 1 resulting from the thermal evaporation of copper (Cu) has an affinity for plating so as to facilitate the plating step (S300), may exhibit high adhesion to the plating layer 2 resulting from the plating step (S300), and shows a black color upon thermal evaporation.

The step of forming the thin-film deposition layer 1 (S100) is preferably implemented by subjecting the target material to vacuum deposition in an oxygen gas atmosphere or a nitrogen gas atmosphere to form an oxide film or a nitride film.

The step of forming the thin-film deposition layer 1 (S100) is preferably implemented by subjecting the target material, such as carbon or a metal including titanium, chromium, copper, nickel, aluminum or silver, to sputtering in an oxygen gas atmosphere or a nitrogen gas atmosphere to form an oxide film or a nitride film on one surface of the transparent substrate 10.

The step of forming the thin-film deposition layer 1 (S100) may be performed in a manner in which the target material, such as an oxide, including titanium oxide (TiO₂), chromium oxide (CrO₂), copper oxide (CuO), nickel oxide (NiO), aluminum oxide (Al₂O₃), or silver oxide (AgO), is subjected to sputtering, thus forming an oxide film on one surface of the transparent substrate 10, or in which the target material, such as a nitride, including titanium nitride (TiN) or copper nitride (CuN), is subjected to sputtering, thus forming a nitride film on one surface of the transparent substrate 10.

Thereby, the oxide film or nitride film may be strongly and firmly attached to the transparent substrate 10, and it may be easy to accurately form the oxide film or nitride film to a preset thickness on one surface of the transparent substrate 10.

The oxide film or nitride film has a reflectance of 30% or less, thus preventing glare due to reflections from the electrode and enhancing the adhesion between the electrode and the transparent substrate 10.

The etching step (S200) may include forming a photosensitive layer 4 on the thin-film deposition layer 1 (S211), exposing and developing the photosensitive layer 4 to form a cover pattern 4a corresponding to a touch-sensing circuit pattern in the photosensitive layer 4 (S212), and etching the thin-film deposition layer 1 covered by the cover pattern 4a.

The etching step (S200) may further include removing the cover pattern 4a from the etched thin-film deposition layer 1 (S214).

More specifically, forming the cover pattern 4a (S212) is performed by covering the photosensitive layer 4 with a mask 5 having therein a pattern hole 5a corresponding to the touch-sensing circuit pattern, and exposing the photosensitive layer 4 so that only the portion to which light is applied is cured so as not to dissolve in a developer solution, while the portion to which light is not applied is dissolved in the developer solution. Briefly, the portion of the photosensitive layer 4 corresponding to the pattern hole 5a, that is, the cover pattern 4a, is left behind, and the remaining portion is dissolved in the developer solution and removed.

The photosensitive layer 4 may be formed by applying a dry film or a photoresist solution.

The photosensitive layer 4 may be formed through spraying, coating, gravure coating, or electrospinning.

Electrospinning enables an electrospun photosensitive layer 4 to be formed to a thickness of 1 to 10 μm. The electrospinning process is performed in a manner in which a photosensitive polymer solution is sprayed together with compressed air using an electrospinning nozzle under the condition that electric power is applied to the thin-film deposition layer 1, thus forming the electrospun photosensitive layer 4 on the thin-film deposition layer 1.

In the electrospinning process, electric charges are contained in the sprayed photosensitive polymer, and thus the photosensitive polymer solution is not agglomerated but is efficiently dispersed while being sprayed, thereby forming the electrospun photosensitive layer 4 in the form of a thin film having a thickness of 5 μm or less.

In the electrospinning process, the electrospun photosensitive layer 4 is formed on the thin-film deposition layer 1 under the condition that electric power is applied to the thin-film deposition layer 1, and photosensitive fibers produced by spinning the photosensitive polymer solution are uniformly applied on and strongly attached to the thin-film deposition layer 1 due to the difference in potential.

When the electrospun photosensitive layer 4 is formed using the electrospinning process, it has to be cured. To this end, the electrospun photosensitive layer 4 is cured using UV curing, laser curing, or e-beam curing.

The plating step (S300) is performed by subjecting the thin-film deposition layer 1 to electroplating or electroless plating with gold (Au), silver (Ag) or copper (Cu).

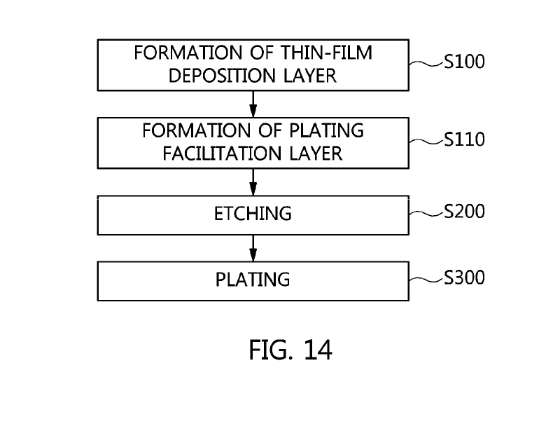

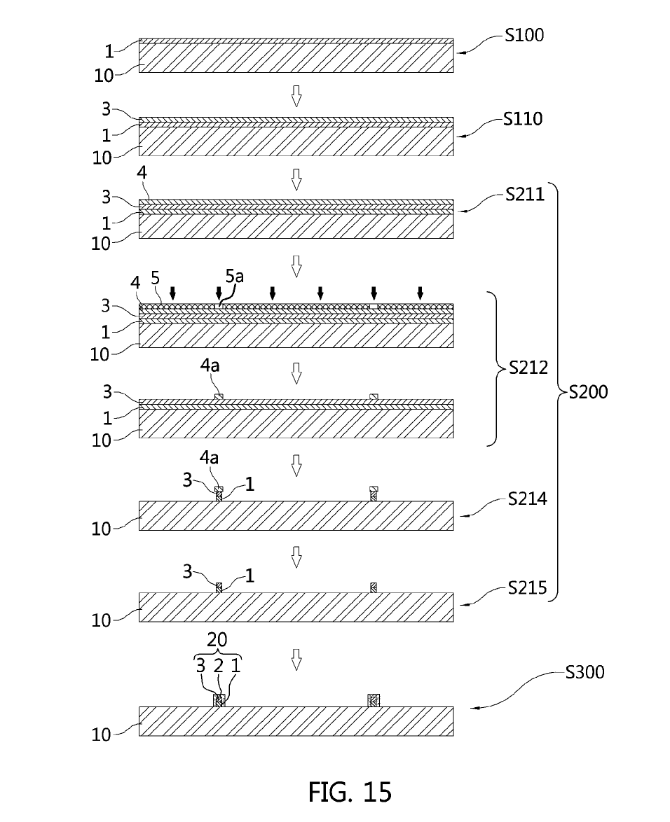

With reference to FIGS. 14 and 15, the method of manufacturing the touch sensor for a touch screen panel according to an embodiment of the present invention preferably further includes forming a plating facilitation layer 3 on the thin-film deposition layer 1 (S110), after the step of forming the thin-film deposition layer 1 (S100) and before the etching step (S200).

The step of forming the plating facilitation layer 3 (S110) may be performed by printing a conductive paste containing at least one selected from among copper (Cu), nickel (Ni), silver (Ag), gold (Au), tin (Sn), aluminum (Al), and palladium (Pd) on the thin-film deposition layer 1 and drying it, thus forming a plating facilitation layer 3, or may include forming a plating facilitation layer 3 through printing, drying, and firing.

The conductive paste may include at least one selected from among copper (Cu), nickel (Ni), silver (Ag), gold (Au), tin (Sn), aluminum (Al), and palladium (Pd), which are in a powder phase.

The step of forming the plating facilitation layer 3 (S110) may be carried out using vacuum deposition to form the plating facilitation layer 3.

The vacuum deposition process may include, for example, any one selected from among thermal evaporation, e-beam evaporation, laser deposition, sputtering, and arc ion plating. The step of forming the plating facilitation layer 3 (S110) may be performed by subjecting any one selected from among copper (Cu), nickel (Ni), silver (Ag), gold (Au), tin (Sn), aluminum (Al), and palladium (Pd) to vacuum deposition to form the plating facilitation layer 3 on the thin-film deposition layer 1.

The vacuum deposition process is advantageous because the plating facilitation layer 3 may be readily formed on the thin-film deposition layer 1, thus simplifying the manufacturing process, reducing manufacturing costs, and enabling precise control of the thickness of the plating facilitation layer 3.

The etching step (S200) is performed by removing the portions of the plating facilitation layer 3 and the thin-film deposition layer 1 other than the portions corresponding to the touch-sensing circuit pattern, and the specific process thereof is as described above, and thus a redundant description thereof is omitted.

The plating step (S300) is performed under the condition that the plating facilitation layer 3 is formed on the thin-film deposition layer 1, thus forming the plating layer 2 that covers the plating facilitation layer 3 and the thin-film deposition layer 1. For example, gold (Au), silver (Ag) or copper (Cu) is subjected to electroplating or electroless plating.

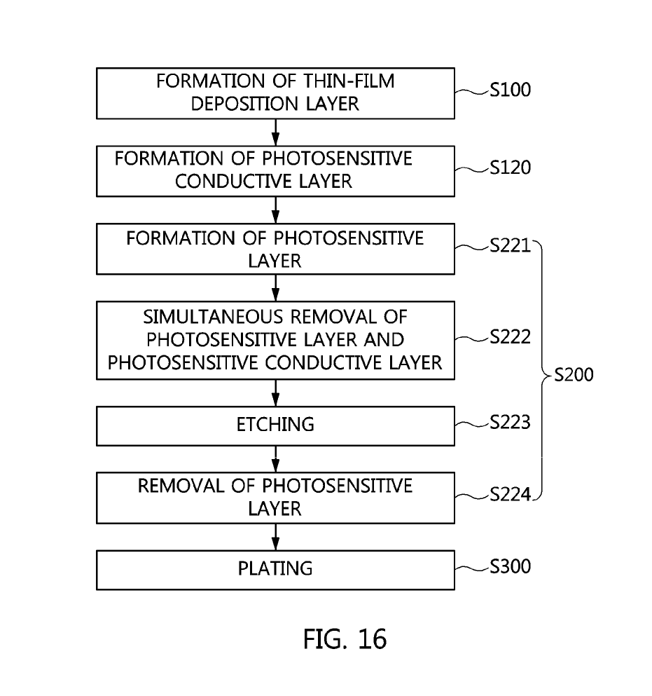

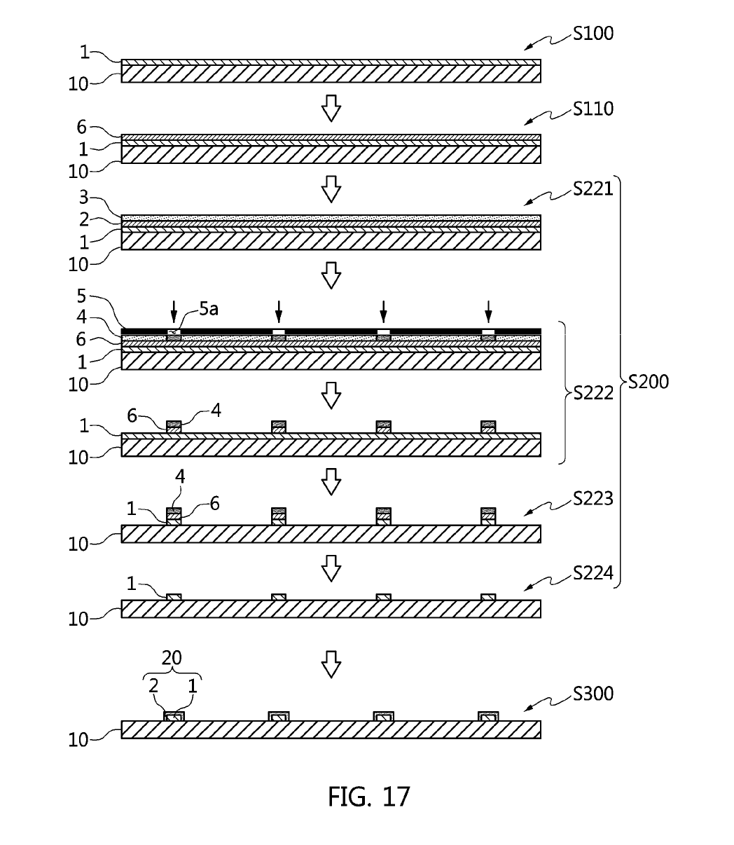

With reference to FIGS. 16 and 17, the method of manufacturing the touch sensor for a touch screen panel according to an embodiment of the present invention preferably further includes forming a photosensitive conductive layer 6 on the thin-film deposition layer 1 (S120), after the step of forming the thin-film deposition layer 1 (S100) and before the etching step (S200).

The photosensitive conductive layer 6 is formed of a conductor, which is removable by the developer solution for removing the photosensitive layer 4 and has a light reflectance of a predetermined level or more, and may be an aluminum layer, or an aluminum alloy layer containing aluminum, or may be a molybdenum layer or a molybdenum alloy layer containing molybdenum. Furthermore, the aluminum alloy layer may be exemplified by AlNd, AlNb, or AlSi.

The photosensitive conductive layer 6 is preferably formed of a material that has a light reflectance of 80% or more, enables efficient exposure and development, and is removable by the developer solution for removing the photosensitive layer 4 to thus simplify the manufacturing process. Examples of the material thereof may include aluminum and aluminum alloys (AlNd, AlNb, AlSi).

The photosensitive conductive layer 6 may be formed of any conductor that is removable by the developer solution for removing the photosensitive layer 4. In the present invention, an aluminum layer, which is inexpensive and highly conductive, is preferably used. The aluminum layer has a high light reflectance of 85 to 88%, thus enabling efficient exposure and development of the photosensitive layer 4 and the accurate formation of a fine circuit pattern.

The step of forming the photosensitive conductive layer 6 (S120) is preferably performed by subjecting a conductor, which is removable by the developer solution for removing the photosensitive layer 4, to vacuum deposition.

Vacuum deposition enables the photosensitive conductive layer 6 to be uniformly formed to a thickness of 1 to 10 μm on the surface of the transparent substrate 10.

The vacuum deposition process may include thermal evaporation, e-beam evaporation, laser deposition, sputtering, or arc ion plating.

The etching step includes forming a photosensitive layer 4 on the photosensitive conductive layer 6 (S221), exposing the photosensitive layer 4, and developing it using a developer solution, thus simultaneously removing portions of the photosensitive layer 4 and the photosensitive conductive layer 6 other than a pattern corresponding to a touch-sensing circuit pattern (S222), and etching the thin-film deposition layer 1 in the form of a touch-sensing circuit pattern (S223).

The step of forming the photosensitive conductive layer 6 (S120) may include forming the photosensitive layer 4 using a casting process.

The casting process may be conducted using comma roll coating, gravure coating, doctor blading, or spraying, whereby the photosensitive layer 4 is formed to a thickness of 1 to 5 μm on the thin-film deposition layer 1.

The step of forming the photosensitive conductive layer 6 (S120) may include forming the photosensitive layer 4 through electrospinning.

The electrospinning process enables an electrospun photosensitive layer 4 to be formed to a thickness of 1 to 10 μm. The electrospinning process is performed in a manner in which a photosensitive polymer solution is sprayed together with compressed air using an electrospinning nozzle under the condition that electric power is applied to the photosensitive conductive layer 6, thus forming the electrospun photosensitive layer 4 on the photosensitive conductive layer 6.

In the electrospinning process, electric charges are contained in the sprayed photosensitive polymer, and thus the photosensitive polymer solution is not agglomerated but is efficiently dispersed while being sprayed, thus forming the electrospun photosensitive layer 4 in the form of a thin film having a thickness of 5 μm or less.

In the electrospinning process, the electrospun photosensitive layer 4 is formed on the photosensitive conductive layer 6 under the condition that electric power is applied to the photosensitive conductive layer 6, and photosensitive fibers produced by spinning the photosensitive polymer solution are uniformly applied on and strongly attached to the photosensitive conductive layer 6 due to the difference in potential.

When the electrospun photosensitive layer 4 is formed using the electrospinning process, polymerization does not occur well upon exposure and thus the electrospun photosensitive layer 4 has to be cured. To this end, the electrospun photosensitive layer 4 is cured using UV curing, laser curing, or e-beam curing.

Since the photosensitive conductive layer 6 has a reflectance of a predetermined level, that is, 80% or more, polymerization is efficiently carried out upon exposure, without the need to cure the electrospun photosensitive layer 4. When the electrospun photosensitive layer 4 is formed through electrospinning, curing the photosensitive layer 4 for exposure and development may be obviated, thus simplifying the manufacturing process and reducing manufacturing costs.

Simultaneous removal of the portions of the photosensitive layer 4 and the photosensitive conductive layer 6 (S222) is performed by covering the photosensitive layer 4 with a mask 5 having therein a pattern hole 5a corresponding to the touch-sensing circuit pattern, and exposing the photosensitive layer 4 so that only the portion to which light is applied is cured so as not to be dissolved in a developer solution, while the portion to which light is not applied is dissolved in the developer solution. Briefly, only the portions of the photosensitive layer 4 and the photosensitive conductive layer 6 corresponding to the pattern hole 5a, that is, the touch-sensing circuit pattern, are left behind, and the portions of the photosensitive layer 4 and the photosensitive conductive layer 6 other than the portions corresponding to the touch-sensing circuit pattern are dissolved in the developer solution and removed therewith, thereby obviating the additional etching process in which the photosensitive conductive layer 6 is etched to form a touch-sensing circuit pattern after the developing process, ultimately simplifying the manufacturing process.

The photosensitive conductive layer 6 is formed of a conductor such as aluminum, an aluminum alloy, or molybdenum, which may be removed together with the photosensitive layer 4 by the developer solution, whereby the portion thereof other than the touch-sensing circuit pattern may be removed together with the photosensitive layer 4 when exposing and developing the photosensitive layer 4.

The developer solution is used to remove the conductor, such as aluminum, the aluminum alloy, or molybdenum, and the photosensitive layer 4, and is exemplified by a carbonate-based high-alkaline solution having a pH of 10 or more. The developer solution may include K₂CO₃ or Na₂CO₃.

As the developer solution, any material may be used so long as it may simultaneously remove the photosensitive layer 4 and the photosensitive conductive layer 6 in the developing process.

The photosensitive conductive layer 6 is removed together with the photosensitive layer 4 using the developer solution after exposure, without the need for an additional removal process, thus simplifying the manufacturing process, increasing exposure efficiency due to high light reflectance, and enabling finer and more accurate formation of the pattern corresponding to the touch-sensing circuit pattern resulting from exposure. Ultimately, the touch-sensing circuit pattern may be formed more finely and accurately through etching.

The etching process (S223) is performed in a manner in which the portion of the thin-film deposition layer 1, other than the touch-sensing circuit pattern, is removed through etching using the photosensitive conductive layer 6 and the photosensitive layer 4 provided in the form of the pattern corresponding to the touch-sensing circuit pattern on the thin-film deposition layer 1.

Specifically, the photosensitive conductive layer 6 and the photosensitive layer 4 are provided in a shape corresponding to the touch-sensing circuit pattern on the thin-film deposition layer 1, and the etching step (S500) is performed in a manner in which the portion of the thin-film deposition layer 1 other than the portion on which the photosensitive conductive layer 6 and the photosensitive layer 4 are formed is removed through etching, thereby forming the thin-film deposition layer 1 in a shape corresponding to the touch-sensing circuit pattern.

After the etching process (S223), the remaining photosensitive layer 4, which covers the thin-film deposition layer 1, is removed (S224). Upon removing the photosensitive layer 4, both the photosensitive conductive layer 6 and the photosensitive layer 4 are simultaneously removed from the thin-film deposition layer 1, provided in the shape corresponding to the touch-sensing circuit pattern.

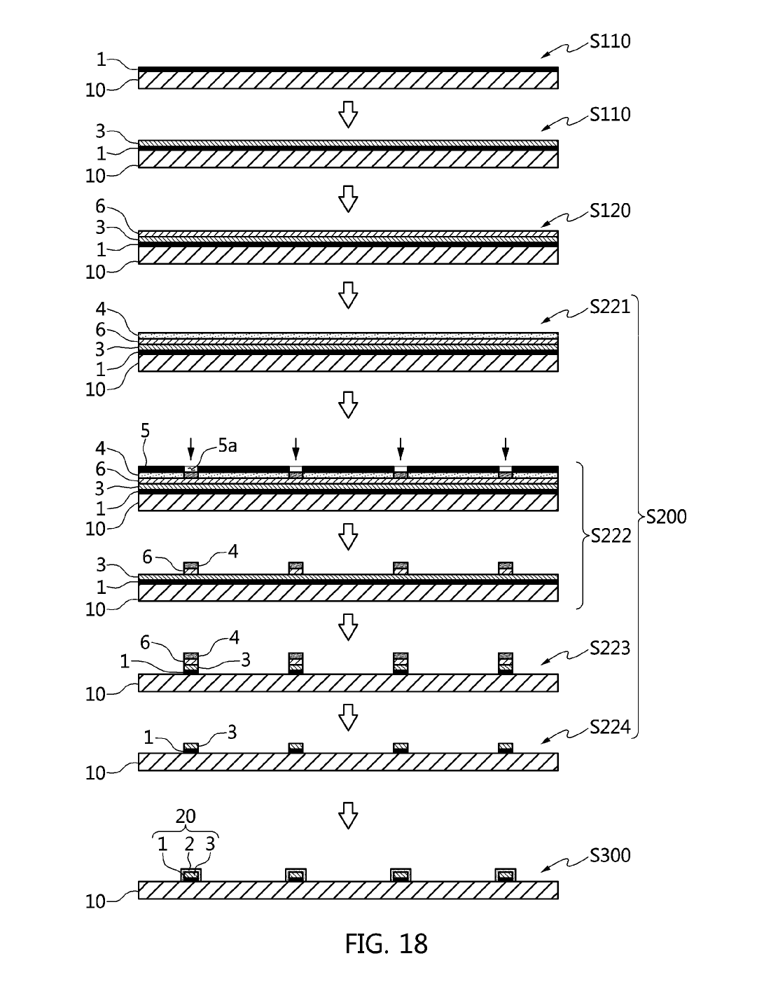

With reference to FIG. 18, the step of forming the photosensitive conductive layer 6 (S120) may be performed by forming the photosensitive conductive layer 6 on the plating facilitation layer 3 after the step of forming the plating facilitation layer 3 (S110).

In this case, the portions of the thin-film deposition layer 1 and the plating facilitation layer 3 other than the touch-sensing circuit pattern are removed through etching.

Also, the plating step (S300) is carried out under the condition that the plating facilitation layer 3 is formed on the thin-film deposition layer 1 to form the plating layer 2, which covers the plating facilitation layer 3 and the thin-film deposition layer 1. This step is performed by subjecting gold (Au), silver (Ag) or copper (Cu) to electroplating or electroless plating.

In the present invention, the strength of adhesion between the transparent substrate 10 and the touch-sensing circuit pattern may be increased, thereby precisely forming a touch-sensing circuit pattern having a fine line width and increasing the durability of the touch-sensing circuit pattern.

In the present invention, the touch sensor for a touch screen panel enables a consistent touch speed and multi-touch capability, thus ensuring the operational reliability of products. Furthermore, the touch-sensing circuit pattern is not damaged even in the event of warpage, making it suitable for application to flexible displays, and the operational reliability of products may be assured due to the consistent touch speed and multi-touch capability of the flexible display.

In the present invention, the touch-sensing circuit pattern is formed through deposition and plating, thereby simplifying the manufacturing process and significantly reducing manufacturing costs.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A touch sensor for a touch screen panel, comprising:
a transparent substrate; and
a touch-sensing circuit pattern formed on the transparent substrate so as to sense a touch on the touch screen panel,
wherein the touch-sensing circuit pattern comprises a thin-film deposition layer formed through deposition and a plating layer formed through plating on the thin-film deposition layer.

2. The touch sensor of claim 1, wherein the thin-film deposition layer comprises any one selected from among chromium (Cr), molybdenum (Mo), titanium (Ti), tungsten (W), nickel-chromium (NiCr), titanium-tungsten (TiW), and copper (Cu).

3. The touch sensor of claim 1, wherein the thin-film deposition layer comprises thermally evaporated copper.

4. The touch sensor of claim 1, wherein the thin-film deposition layer comprises an oxide film or a nitride film.

5. The touch sensor of claim 4, wherein the oxide film comprises any one selected from among titanium oxide (TiO₂), chromium oxide (CrO₂), copper oxide (CuO), nickel oxide (NiO), aluminum oxide (Al₂O₃), and silver oxide (AgO), and
the nitride film comprises titanium nitride (TiN) or copper nitride (CuN).

6. The touch sensor of claim 1, further comprising a plating facilitation layer disposed between the thin-film deposition layer and the plating layer.

7. The touch sensor of claim 6, wherein the plating facilitation layer comprises any one selected from among copper (Cu), nickel (Ni), silver (Ag), gold (Au), tin (Sn), aluminum (Al), and palladium (Pd).

8. The touch sensor of claim 1, wherein the touch-sensing circuit pattern comprises an X-axis sensing circuit part having a plurality of X-axis electrodes spaced apart from each other in a transverse direction and a Y-axis sensing circuit part having a plurality of Y-axis electrodes spaced apart from each other in a longitudinal direction, and
the X-axis sensing circuit part and the Y-axis sensing circuit part are formed on a same surface of the transparent substrate.

9. The touch sensor of claim 1, wherein the touch-sensing circuit pattern comprises an X-axis sensing circuit part having a plurality of X-axis electrodes spaced apart from each other in a transverse direction, which is provided on one of two surfaces of the transparent substrate, and a Y-axis sensing circuit part having a plurality of Y-axis electrodes spaced apart from each other in a longitudinal direction, which is provided on a remaining surface thereof.

10. A touch screen panel using the touch sensor of claim 1.

11. A method of manufacturing a touch sensor for a touch screen panel, comprising:
forming a thin-film deposition layer through deposition on a transparent substrate;
etching a portion of the thin-film deposition layer other than a portion corresponding to a touch-sensing circuit pattern; and
plating the thin-film deposition layer that remains on the transparent substrate after the etching.

12. The method of claim 11, wherein the forming the thin-film deposition layer is performed using any one deposition process selected from among thermal evaporation, e-beam evaporation, laser deposition, sputtering, and arc ion plating.

13. The method of claim 11, further comprising forming a plating facilitation layer on the thin-film deposition layer after the forming the thin-film deposition layer and before the etching.

14. The method of claim 13, wherein the forming the plating facilitation layer is performed through vacuum deposition.

15. The method of claim 11, further comprising forming a photosensitive conductive layer on the thin-film deposition layer after the forming the thin-film deposition layer and before the etching,
wherein the etching comprises:
forming a photosensitive layer on the photosensitive conductive layer;
exposing the photosensitive layer and developing the photosensitive layer using a developer solution, thus simultaneously removing portions of the photosensitive layer and the photosensitive conductive layer other than a pattern corresponding to a touch-sensing circuit pattern;
etching the thin-film deposition layer in a shape corresponding to the touch-sensing circuit pattern; and
removing the remaining photosensitive layer that covers the thin-film deposition layer.

16. The method of claim 15, wherein the forming the photosensitive conductive layer comprises forming the photosensitive layer through any one selected from among comma roll coating, gravure coating, doctor blading, and spraying.

17. The method of claim 15, wherein the forming the photosensitive conductive layer comprises forming the photosensitive layer through electrospinning.

18. The method of claim 15, wherein the photosensitive conductive layer comprises an aluminum layer or an aluminum alloy layer containing aluminum.

19. The method of claim 15, wherein the developer solution comprises a carbonate-based high-alkaline solution having a pH of 10 or more.

20. The method of claim 15, wherein the developer solution comprises K₂CO₃ or Na₂CO₃.
